(19) United States
(12) Patent Application Publication
(10) Pub. No.: US 2011/0201209 A1
(43) Pub. Date: Aug. 18, 2011

(54) Method and System for Wafer-Level Planarization of a Die-to-Wafer System

(75) Inventors: Sharath Hosali, Austin, TX (US); Gregory Smith, Mineola, TX (US); Larry Smith, Austin, TX (US)

(73) Assignee: SEMATECH, INC.

(21) Appl. No.: 12/707,589

(22) Filed: Feb. 17, 2010

(51) Int. Cl. H01L 21/3105; B05C 11/02

(52) U.S. Cl. 438/759; 118/44; 257/E21.244

(57) ABSTRACT

Methods and systems for planarization of a die-to-wafer integration. A planarization coating may be applied to the die-to-wafer assembly, and a planarization plate may be used in the planarization process. The planarization plate may include perforations configured to allow a portion of the planarization coating to extrude through the planarization plate.

### BACKGROUND OF THE INVENTION

The present methods, devices, and systems relate generally to the field of semiconductor fabrication, and more particularly to the planarization of a die-to-wafer integration.

Vertical integration of semiconductor devices, commonly referred to as “3D interconnect,” may be accomplished using die-to-wafer or wafer-to-wafer flows by which a “donor” die or wafer is stacked on top of a “host” wafer. Die-to-wafer 3D stacking has possible yield and cost advantages. For example, die-to-wafer processes include the ability to pre-screen or otherwise test donor die, thus allowing the manufacturer to select only devices that have passed the test for further integration and discard the bad ones.

In one implementation of a die-to-wafer integration, the die are bonded face down to the host wafer. In contrast to wafer-to-wafer bonding (in which further processing of the backside of the donor wafer is possible to enable stacking of yet additional layers of active devices), further wafer-level processing of the die-attached wafer may be problematic due to the non-planar topography of the attached die.

Methods to flatten high topography surfaces with an optically flat plate are known in the art. U.S. Pat. Nos. 6,797,607; 6,589,889; and 6,716,767 disclose the use of nanoporous silica or polymer materials that can be pressed down on a wafer by the flat plate to obtain flat surfaces. The material may then be cured in situ, and the flat plate removed so that a planar layer is retained. Typical applications of the disclosed methods are “within wafer” applications where the feature sizes involved in the planarization (e.g., several hundreds of microns or smaller) are much smaller than the topography features involved in planarization of die-to-wafer systems (e.g., a few millimeters to many centimeters)

### SUMMARY OF THE INVENTION

Embodiments of the present methods for planarization of a die-to-wafer integration may include providing a die-to-wafer assembly, applying a planarization coating, and contacting the planarization coating with a planarization plate with sufficient pressure to transfer an impression of the planarization plate to the planarization coating. The die-to-wafer assembly may have a die side and a wafer side, and may include a substrate disposed at the wafer side, and a plurality of die fixed to the substrate at the die side. The plurality of die may be disposed at the die side and extend by a die height from a surface of the substrate. The planarization coating may contact the surface of the substrate and have a thickness that is greater than or equal to the die height. The planarization plate may have a plurality of perforations configured to allow an extruded portion of the planarization coating to extrude through the planarization plate.

Some embodiments of the present methods further include moving the planarization plate to cause the extruded portion to shear from the planarization coating. In some embodiments, the moving the planarization plate includes translating in a direction substantially parallel to the surface of the substrate. In some embodiments, the moving the planarization plate includes rotating the planarization plate to cause the extruded portion to shear from the planarization coating. In some embodiments, the rotating the planarization plate includes rotating about an axis substantially normal to the surface of the substrate.

In some embodiments of the present methods, the plurality of die do not all extend from the surface of the substrate by the same amount. In some of these embodiments the die height is the maximum by which any of the plurality of die extend from the surface of the substrate.

Embodiments of the present systems for performing planarization of a die-to-wafer integration include a pedestal configured to support a die-to-wafer assembly, a fluid source configured to apply a planarization coating, and a planarization plate that is operable to contact the planarization coating with sufficient pressure to transfer an impression of the planarization plate to the planarization coating. The die-to-wafer assembly may have a die side and a wafer side, and may include a substrate disposed at the wafer side, and a plurality of die fixed to the substrate at the die side. The plurality of die may be disposed at the die side and extend by a die height from a surface of the substrate. The planarization coating may contact the surface of the substrate and have a thickness that is greater than or equal to the die height. The planarization plate may have a plurality of perforations configured to allow an extruded portion of the planarization coating to extrude through the planarization plate.

In some embodiments of the present systems, the planarization plate is further operable to move to cause the extruded portion to shear from the planarization coating. In some embodiments, the movement includes translating in a direction substantially parallel to the surface of the substrate. In some embodiments, the movement includes a rotation that is configured to cause the extruded portion to shear from the planarization coating. In some embodiments, the rotation includes rotating about an axis substantially normal to the surface of the substrate.

In some embodiments of the present systems, the plurality of die do not all extend from the surface of the substrate by the same amount. In some of these embodiments the die height is the maximum by which any of the plurality of die extend from the surface of the substrate.

### BRIEF DESCRIPTION OF THE DRAWINGS

The following drawings form part of the present specification and are included to further demonstrate certain aspects of the present methods and systems. The drawings illustrate by way of example and not limitation. Identical reference numerals do not necessarily indicate an identical structure. Rather, the same reference numeral may be used to indicate a similar feature or a feature with similar functionality. Not every feature of each embodiment is labeled in every figure in which that embodiment appears, in order to keep the figures clear.

FIGS. 1-6 are embodiments of the present systems for performing planarization of a die-to-wafer integration.

FIG. 7 is a flow chart flow chart depicting an embodiment of the present methods for performing planarization of a die-to-wafer integration.

### DESCRIPTION OF ILLUSTRATIVE EMBODIMENTS

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. Thus, a method comprising certain steps is a method that includes at least the recited steps, but is not limited to only possessing the recited steps. Likewise, a device or system comprising certain elements includes at least the recited elements, but is not limited to only possessing the recited elements.

The terms “substantially,” “about,” and their variations are defined as being largely but not necessarily wholly what is specified as understood by one of ordinary skill in the art, and in one non-limiting embodiment, the substantially refers to ranges within 10%, preferably within 5%, more preferably within 1%, and most preferably within 0.5% of what is specified.

The terms “a” and “an” are defined as one or more than one, unless this application expressly requires otherwise. The term “another” is defined as at least a second or more. The term “coupled” is defined as connected, although not necessarily directly, and not necessarily mechanically.

In one aspect, the present disclosure provides embodiments that are methods for performing planarization of a die-to-wafer integration. Another aspect of the present disclosure provides systems for performing planarization of a die-to-wafer integration.

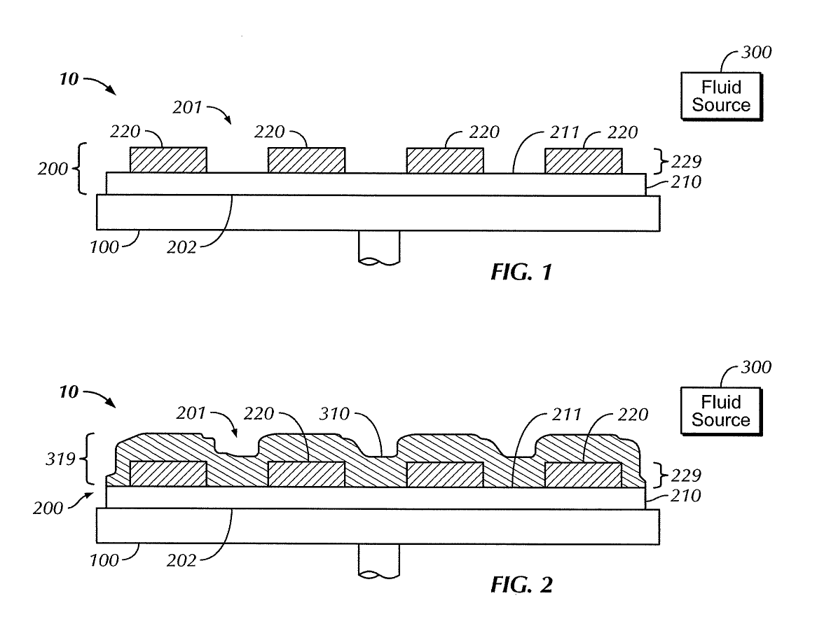

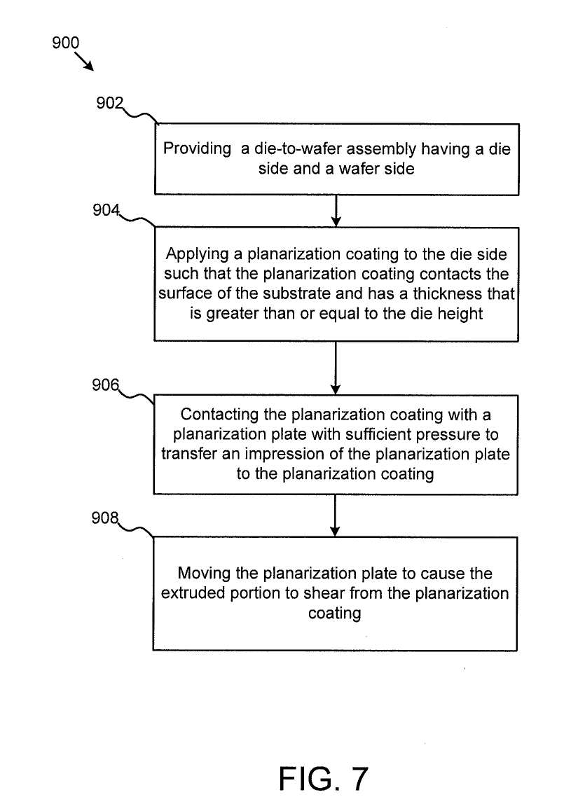

An embodiment of the present system for performing planarization of a die-to-wafer integration is depicted in FIG. 1. In this embodiment, system 10 may be configured to perform a method for performing planarization of a die-to-wafer integration, such as the method depicted in FIG. 7. System 10 may include pedestal 100 that is configured to support die-to-wafer assembly 200. Mechanical clamping, electrostatic clamping, vacuum clamping, or any other suitable method for fixing die-to-wafer assembly 200 to pedestal 100 may be employed by embodiments of the present systems.

Die-to-wafer assembly 200 may include die that are bonded to a host wafer. Die-to-wafer assembly 200 may have die side 201 and wafer side 202, and include substrate 210 positioned at wafer side 202 and die 220 positioned at die side 201. In some embodiments, substrate 210 is a host silicon wafer. In other embodiments of the present systems, substrate 210 may be a host substrate comprising a semiconductor material other than silicon (e.g., GaAs, Germanium). Die 220 may be an integrated circuit die that is fixed (e.g., bonded) to substrate 210 at surface 211, and may extend from surface 211 by die height 229. Some embodiments may include a plurality of die 220 that extend from surface 211 by various distances, with die height 229 being the largest distance by which any of the plurality of die 220 extend.

Referring also to FIG. 2, embodiments of system 10 may also include fluid source 300 configured to apply planarization coating 310 to die side 201 of die-to-wafer assembly 200. Planarization coating 310 can be applied onto surface 211 of substrate 210 such that an amount of planarization coating 310 having thickness 319 that is greater than or equal to die height 229 substantially covers surface 211. Planarization coating 310 may include, for example, nanoporous silica or polymer materials such as those disclosed in U.S. Pat. Nos. 6,797,607; 6,589,889; and 6,716,767; each of which is incorporated by reference in its entirety.

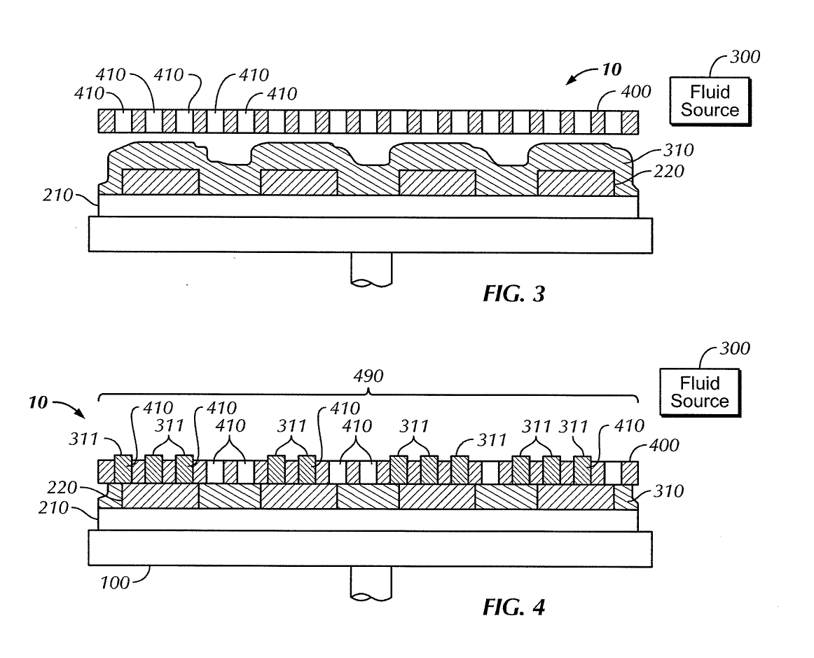

Planarization plate 400, as depicted in FIGS. 3-6, may facilitate planarization of die-to-wafer assembly 200. After application of planarization coating 310 by fluid source 300, planarization plate 400 may be used to contact planarization coating 310 with sufficient pressure to transfer an impression of a surface of planarization plate 400 to planarization coating 310. Planarization plate 400 may include a plurality of perforation 410 that are configured to allow a portion of viscous or semi-viscous planarization coating 310 to extrude through perforation 410, thereby allowing removal of excess portions of planarization coating 310 through perforation 410 when pressure is applied to planarization coating 310 by planarization plate 400. For example, referring to FIG. 4, application of pressure to planarization plate 400 to transfer an impression of planarization plate 400 at area of impression 490 may result in extruded portion 311 escaping through perforation 410. The ability of extruded portion 311 to escape through planarization plate 400 eliminates stresses that may be induced in die 220 and substrate 210 if the entirety of excess planarization coating 310 displaced by planarization plate 400 were to be forced to escape by flowing between substrate 210 and planarization plate 400 (e.g., flowing out of the sides of die-to-wafer assembly 200).

Planarization plate 400 may comprise materials that are configured to release planarization coating 310 from contact with planarization plate 400 without sticking (e.g., PTFE). The configuration of perforation 410 (e.g., pattern of perforations and size of each perforation) may be configured based on the size of die 220 (e.g., die height 229), the spacings between individual die 220, the size of area of impression 490, and properties of planarization coating 310. For example, the size of each perforation and overall areal density of the pattern of perforations should be chosen with an awareness of the viscosity of planarization coating 310. Low viscosity planarization coating 310 will allow the use of lower areal density and generally smaller perforations in planarization plate 400 than would high viscosity planarization coating 310.

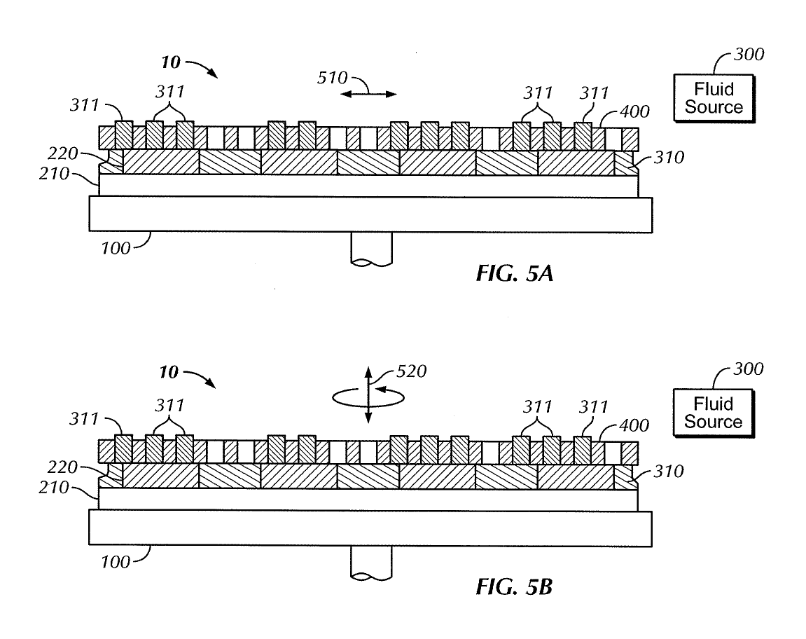

Referring to FIGS. 5A and 5B, embodiments of system 10 may be configured to shear extruded portion 311 from planarization coating 310 before the material is fully hardened, thereby minimizing the potential for rip-out of the extruded material. FIG. 5A depicts an embodiment of system 10 in which the shearing of extruded portion 311 is accomplished by a translation of planarization plate 400 along translation direction 510. Translation direction 510 may be substantially parallel to surface 211 of substrate 210. FIG. 5B depicts an embodiment of system 10 in which the shearing of extruded portion 311 is accomplished by a rotation of planarization plate 400 about rotation axis 520. Rotation axis 520 may be substantially normal to surface 211 of substrate 210. Some embodiments may accomplish shearing of extruded portion 311 through movement that includes a combination of translations and/or rotations of planarization plate 400.

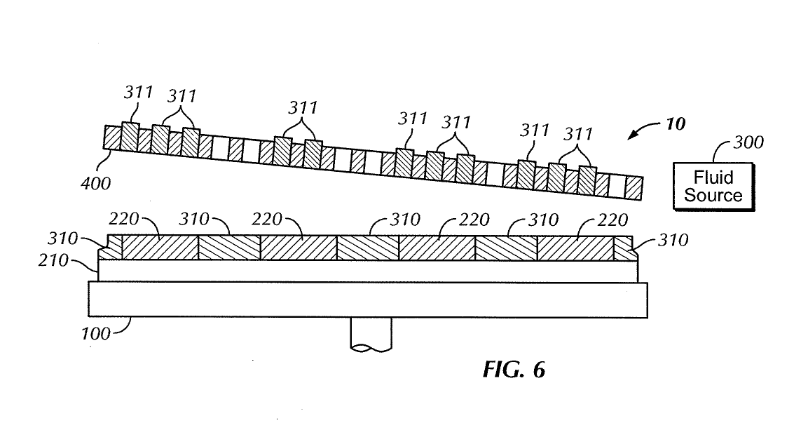

FIG. 6 depicts removal of planarization plate 400, and the resulting removal of extruded portion 311. A planarized die-to-wafer assembly 200 that includes planarization coating 310 providing a surface that is substantially planar with die 220 may result from performance of the present methods by embodiments of the present systems.

FIG. 7 is a flow diagram illustrating an embodiment of the present methods for performing planarization of a die-to-wafer integration that may be performed by, for example, an embodiment of the present systems as described above and depicted in FIGS. 1-6. Method 900 may include providing a die-to-wafer assembly having a die side and a wafer side (step 902); applying a planarization coating to the die side such that the planarization coating contacts the surface of the substrate and has a thickness that is greater than or equal to the die height (step 904); contacting the planarization coating with a planarization plate with sufficient pressure to transfer an impression of the planarization plate to the planarization coating (step 906); and moving the planarization plate to cause the extruded portion to shear from the planarization coating (step 908).

It should be understood that the operational flow diagram of FIG. 7 is intended only as an example, and one of ordinary skill in the art will recognize that in alternative embodiments certain block may be performed in a different order than the order depicted, certain blocks may be performed in parallel, certain blocks of operation may be omitted completely, and additional operational blocks may be added. Thus, the present methods are not intended to be limited only to the operational flow diagrams of FIG. 7, but rather such operational flow diagram is intended solely as an example that renders the disclosure enabling for many other operational flow diagrams for implementing the present methods.

Descriptions of well known assembly techniques, components, and equipment have been omitted so as not to unnecessarily obscure the present methods, apparatuses, an systems in unnecessary detail. The descriptions of the present methods and apparatuses are exemplary and non-limiting. Certain substitutions, modifications, additions and/or rearrangements falling within the scope of the claims, but not explicitly listed in this disclosure, may become apparent to those of ordinary skill in the art based on this disclosure. For example, many different configurations of perforation 410 may be used by embodiments of the present systems.

The appended claims are not to be interpreted as including means-plus-function limitations, unless such a limitation is explicitly recited in a given claim using the phrase(s) “means for” and/or “step for,” respectively.

What is claimed is:

1. A method for planarization of a die-to-wafer integration, the method comprising:
providing a die-to-wafer assembly having a die side and a wafer side, the die-to-wafer assembly including:
a substrate disposed at the wafer side; and
a plurality of die fixed to the substrate, the plurality of die being disposed at the die side and extending by a die height from a surface of the substrate;
applying a planarization coating to the die side, the planarization coating contacting the surface of the substrate and having a thickness that is greater than or equal to the die height; and
contacting the planarization coating with a planarization plate with sufficient pressure to transfer an impression of the planarization plate to the planarization coating, the planarization plate having a plurality of perforations configured to allow an extruded portion of the planarization coating to extrude through the planarization plate.

2. The method of claim 1, further comprising moving the planarization plate to cause the extruded portion to shear from the planarization coating.

3. The method of claim 2, the moving the planarization plate comprising translating the planarization plate in a direction substantially parallel to the surface of the substrate.

4. The method of claim 2, the moving the planarization plate comprising rotating the planarization plate to cause the extruded portion to shear from the planarization coating.

5. The method of claim 4, the rotating the planarization plate comprising rotating about an axis substantially normal to the surface of the substrate.

6. The method of claim 1, where:
the plurality of die do not all extend from the surface of the substrate by the same amount; and
the die height being the maximum by which any of the plurality of die extend from the surface of the substrate.

7. The method of claim 6, further comprising moving the planarization plate to cause the extruded portion to shear from the planarization coating.

8. The method of claim 7, the moving the planarization plate comprising translating the planarization plate in a direction substantially parallel to the surface of the substrate.

9. The method of claim 7, the moving the planarization plate comprising rotating the planarization plate to cause the extruded portion to shear from the planarization coating.

10. The method of claim 9, the rotating the planarization plate comprising rotating about an axis substantially normal to the surface of the substrate.

11. A system for performing planarization of a die-to-wafer integration, the system comprising:
a pedestal configured to support a die-to-wafer assembly having a die side and a wafer side, the die-to-wafer assembly including:
a substrate disposed at the wafer side; and
a plurality of die fixed to the substrate, the plurality of die being disposed at the die side and extending by a die height from a surface of the substrate;
a fluid source configured to apply a planarization coating to the die side, the planarization coating contacting the surface of the substrate and having a thickness that is greater than or equal to the die height; and
a planarization plate that is operable to contact the planarization coating with sufficient pressure to transfer an impression of the planarization plate to the planarization coating, the planarization plate having a plurality of perforations configured to allow an extruded portion of the planarization coating to extrude through the planarization plate.

12. The system of claim 11, the planarization plate being further operable to move to cause the extruded portion to shear from the planarization coating.

13. The system of claim 12, the movement comprising translating the in a direction substantially parallel to the surface of the substrate.

14. The system of claim 12, the movement comprising a rotation that is configured to cause the extruded portion to shear from the planarization coating.

15. The system of claim 14, the rotation comprising rotating about an axis substantially normal to the surface of the substrate.

16. The system of claim 11, where:
the plurality of die do not all extend from the surface of the substrate by the same amount; and
the die height being the greatest amount by which any of the plurality of die extend from the surface of the substrate.

17. The system of claim 16, the planarization plate being further operable to move to cause the extruded portion to shear from the planarization coating.

18. The system of claim 17, the movement comprising translating in a direction substantially parallel to the surface of the substrate.

19. The system of claim 17, the movement comprising a rotation that is configured to cause the extruded portion to shear from the planarization coating.

20. The system of claim 19, the rotation comprising rotating about an axis substantially normal to the surface of the substrate.
